(19) United States
(12) Patent Application Publication
(10) Pub. No.: US 2025/0364953 A1
(43) Pub. Date: Nov. 27, 2025

(54) POWER AMPLIFIER CIRCUIT AND POWER AMPLIFICATION DEVICE

(71) Applicant: Murata Manufacturing Co, Ltd., Nagaokakyo-shi (JP)

(72) Inventor: Takayuki KAWANO, Nagaokakyo-shi (JP)

(21) Appl. No.: 19/293,254

(22) Filed: Aug. 7, 2025

Related U.S. Application Data
(63) Continuation of application No. PCT/JP2024/006492, filed on Feb. 22, 2024.

(30) Foreign Application Priority Data
Mar. 28, 2023 (JP) 2023-050758
Jan. 5, 2024 (JP) 2024-000741

(51) Int. Cl. H03F 1/02; H03F 3/24

(52) U.S. Cl. CPC H03F 1/0288; H03F 3/245; H03F 2200/451

(57) ABSTRACT

A power amplifier circuit includes a first coupler that splits a first signal into a second signal and a third signal that is out of phase with the second signal; a carrier amplifier that amplifies the second signal to output a first amplified signal; a peak amplifier that amplifies the third signal to output a second amplified signal; a second coupler that generates a third amplified signal by combining the first amplified signal and the second amplified signal; and a first bias circuit that switches the bias point of the peak amplifier between a first bias point and a second bias point higher than the first bias point.

### CROSS REFERENCE TO RELATED APPLICATION

This is a continuation of International Application No. PCT/JP2024/006492 filed on Feb. 22, 2024 which claims priority from Japanese Patent Application No. 2023-050758 filed on Mar. 28, 2023 and Japanese Patent Application No. 2024-000741 filed on Jan. 5, 2024. The contents of these applications are incorporated herein by reference in their entireties.

### BACKGROUND OF THE DISCLOSURE

### Field of the Disclosure

The present disclosure relates to a power amplifier circuit and a power amplification device.

### Description of the Related Art

There is a Doherty amplifier including a carrier amplifier and a peak amplifier (see, for example, International Publication No. 2008/012898).

### BRIEF SUMMARY OF THE DISCLOSURE

In a power amplification device described in International Publication No. 2008/012898, a bias supplied to the peak amplifier is changed such that the power amplification device transitions from the Doherty amplifier in a low power mode toward a balanced amplifier in a high power mode. However, because this power amplification device includes a λ/4 transmission line, the power amplification device has a large circuit size.

The present disclosure has been made in view of the above problem, and a possible benefit of the present disclosure is to provide a power amplifier circuit and a power amplification device each of which has a small circuit size and is capable of changing the bias point of a peak amplifier.

According to an aspect of the present disclosure, a power amplifier circuit includes a first coupler that splits a first signal into a second signal and a third signal that is out of phase with the second signal; a carrier amplifier that amplifies the second signal to output a first amplified signal; a peak amplifier that amplifies the third signal to output a second amplified signal; a second coupler that generates a third amplified signal by combining the first amplified signal and the second amplified signal; and a first bias circuit that switches the bias point of the peak amplifier between a first bias point and a second bias point higher than the first bias point.

According to another aspect of the present disclosure, a power amplification device includes a semiconductor chip on which the power amplifier circuit is formed, and a substrate on which the semiconductor chip is mounted and a matching circuit is formed upstream or downstream of the power amplifier circuit.

According to another aspect of the present disclosure, a power amplification device includes a first substrate that is comprised of a first compound semiconductor and on which the power amplifier circuit is formed, and a second substrate that is comprised of a single-element semiconductor or a second compound semiconductor and on which an amplifier, which amplifies an input signal to output the first signal, is formed. The first compound semiconductor is different from the second compound semiconductor.

The present disclosure makes it possible to provide a power amplifier circuit and a power amplification device each of which has a small circuit size and is capable of changing the bias point of a peak amplifier.

### BRIEF DESCRIPTION OF THE SEVERAL VIEWS OF THE DRAWINGS

FIG. 1 is a circuit diagram of a power amplifier circuit 101.

FIG. 2 is a plan view of a 90-degree coupler 41 viewed from above.

FIG. 3 is a cross-sectional view taken along section line III-III in FIG. 2.

FIG. 4 is a plan view of a 90-degree coupler 42 viewed from above.

FIG. 5 is a cross-sectional view taken along section line V-V in FIG. 4.

FIG. 6 is a circuit diagram of a power amplifier circuit 101D.

FIG. 7 is a plan view of a 90-degree coupler 141 viewed from above.

FIG. 8 is a cross-sectional view taken along section line VIII-VIII in FIG. 7.

FIG. 9 is a diagram schematically illustrating cross-sections, which are parallel to the xy plane, of a semiconductor chip 11 on which the power amplifier circuit 101D is formed.

FIG. 10 is a graph showing an example of an efficiency characteristic of the power amplifier circuit 101.

FIG. 11 is a graph showing an example of load variation tolerance of the power amplifier circuit 101 in a balanced mode.

FIG. 12 is a graph showing an example of load variation tolerance of the power amplifier circuit 101 in a Doherty mode.

FIG. 13 is a circuit diagram of a power amplifier circuit 102.

FIG. 14 is a circuit diagram of a power amplifier circuit 103.

### DETAILED DESCRIPTION OF THE DISCLOSURE

Embodiments of the present disclosure are described in detail below with reference to the drawings. Also, the same reference number is assigned to the same components, and repeated descriptions of those components are omitted as far as possible.

### First Embodiment

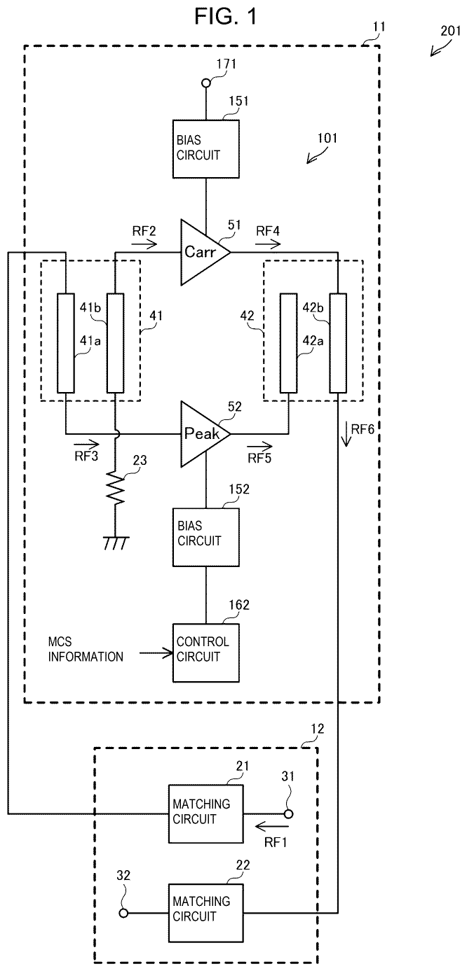

A power amplifier circuit 101 and a power amplification device 201 according to a first embodiment are described. FIG. 1 is a circuit diagram of the power amplifier circuit 101. As illustrated in FIG. 1, the power amplification device 201 is provided in, for example, a communication apparatus that complies with the WiFi (registered trademark) communication standard.

The power amplifier circuit 101 amplifies a signal RF1 (first signal) supplied to an input terminal 31 and outputs an amplified signal RF6 (third amplified signal) from an output terminal 32.

The signal RF1 is, for example, a radio frequency signal. The signal RF1 has been modulated according to, for example, the WiFi communication standard. The frequency of the signal RF1 is, for example, greater than or equal to 5 GHz and less than or equal to 7 GHz. The signal RF1 may have any other frequency.

The power amplification device 201 includes matching circuits 21 and 22 and the power amplifier circuit 101. The matching circuits 21 and 22 are disposed upstream and downstream of the power amplifier circuit 101, respectively. The matching circuits 21 and 22 are formed on, for example, a printed circuit board 12. The power amplifier circuit 101 is formed on a semiconductor chip 11. The semiconductor chip 11 is connected to the printed circuit board 12.

The power amplifier circuit 101 includes 90-degree couplers 41 (first coupler) and 42 (second coupler), a carrier amplifier 51, a peak amplifier 52, bias circuits 151 and 152 (first bias circuit), and a control circuit 162.

In the present embodiment, it is assumed that each of the carrier amplifier 51 and the peak amplifier 52 is implemented by, for example, a bipolar transistor, such as a heterojunction bipolar transistor (HBT). Alternatively, each of the amplifiers may be implemented by any other type of transistor, such as a metal-oxide-semiconductor field-effect transistor (MOSFET). In this case, the base, the collector, and the emitter in the descriptions below are substituted by the gate, the drain, and the source, respectively.

The matching circuit 21 is disposed between the input terminal 31 and the power amplifier circuit 101 and provides the impedance matching between the power amplifier circuit 101 and a circuit (not shown) provided upstream of the input terminal 31.

The matching circuit 22 is disposed between the output terminal 32 and the power amplifier circuit 101 and provides the impedance matching between the power amplifier circuit 101 and loads (not shown), such as a band select switch, a duplexer, an antenna select switch, and an antenna (not shown), that are provided downstream of the output terminal 32.

The 90-degree coupler 41 includes electrodes 41a (first electrode) and 41b (second electrode). The 90-degree coupler 41 splits the signal RF1, which is supplied from the input terminal 31 via the matching circuit 21, into a signal RF2 (second signal) and a signal RF3 (third signal) that is out of phase with the signal RF2.

The electrode 41a of the 90-degree coupler 41 is connected to the input terminal 31 via the matching circuit 21 and includes a first end to which the signal RF1 is supplied and a second end that outputs the signal RF3. The electrode 41b is electromagnetically coupled to the electrode 41a. The electrode 41b includes a first end that outputs the signal RF2 and a second end that is an isolation terminal to which a predetermined potential is supplied. In the present embodiment, the second end of the electrode 41b is connected to a ground via a resistor element 23. The phase of the signal RF3 is delayed from the phase of the signal RF2 by approximately 90 degrees.

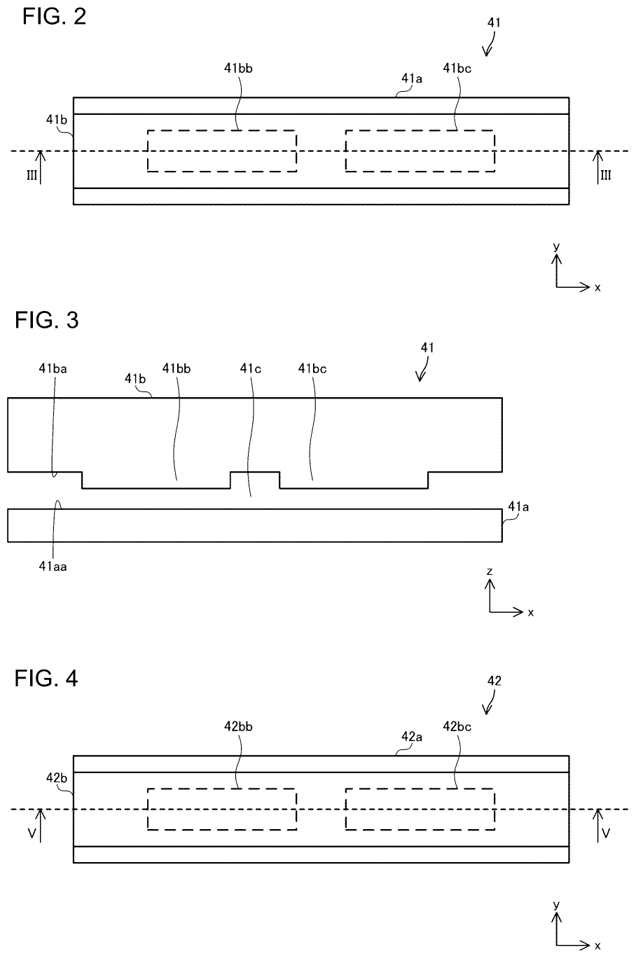

FIG. 2 is a plan view of the 90-degree coupler 41 viewed from above. FIG. 3 is a cross-sectional view taken along line III-III in FIG. 2.

Each diagram may include arrows indicating an x-axis, a y-axis, and a z-axis. The x-axis, the y-axis, and the z-axis form a right-handed three-dimensional orthogonal coordinate system. In the descriptions below, the direction indicated by the arrow of the x-axis is referred to as a positive x-axis side, and the direction opposite the arrow is referred to as a negative x-axis side. This terminology also applies to other axes. Here, the positive z-axis side and the negative z-axis side may also be referred to as “upper side” and “lower side”, respectively. Also, the z-axis direction may be referred to as “stacking direction”. Furthermore, the planes that are orthogonal to the x-axis, the y-axis, and the z-axis may be referred to as a yz plane, a zx plane, and an xy plane, respectively.

As illustrated in FIGS. 2 and 3, the electrodes 41a and 41b extend along the X-axis direction (first direction, second direction) and face each other. In more detail, the electrode 41b is disposed above the electrode 41a. The electrode 41a has a facing surface 41aa, which is an upper surface facing the electrode 41b. The electrode 41b has a facing surface 41ba, which is a lower surface facing the electrode 41a. A dielectric layer 41c is provided between the facing surface 41aa and the facing surface 41ba. The width of the electrode 41b is less than the width of the electrode 41a.

The distance between the electrodes 41a and 41b is not constant. In the present embodiment, protrusions 41bb and 41bc are provided on the lower side of the electrode 41b. The protrusions 41bb and 41bc protrude downward. The distance between the electrodes 41a and 41b is shorter at the protrusions 41bb and 41bc. This makes it possible to increase the capacitance between the electrodes 41a and 41b at the protrusions 41bb and 41bc. The degree of electromagnetic coupling between the electrodes 41a and 41b can be adjusted by adjusting the positions, shapes, and sizes of the protrusions 41bb and 41bc. In particular, in a frequency band greater than or equal to 5 GHz, the length of the 90-degree coupler 41 is often short due to the relationship with the frequency band. Therefore, the impedance of the 90-degree coupler 41 can be adjusted by mainly adjusting the capacitance value. In other words, the impedance of the 90-degree coupler 41 can be more easily optimized by adjusting the capacitance between the electrodes 41a and 41b using the protrusions 41bb and 41bc.

As illustrated in FIG. 1, the carrier amplifier 51 amplifies the signal RF2 supplied from the first end of the electrode 41b of the 90-degree coupler 41 and outputs an amplified signal RF4 (first amplified signal).

The peak amplifier 52 amplifies the signal RF3 supplied from the second end of the electrode 41a of the 90-degree coupler 41 and outputs an amplified signal RF5 (second amplified signal).

The 90-degree coupler 42 includes electrodes 42a (third electrode) and 42b (fourth electrode). The 90-degree coupler 42 combines the amplified signal RF4 with the amplified signal RF5 to generate an amplified signal RF6.

The electrode 42a of the 90-degree coupler 42 includes an open first end, which is an isolation terminal, and a second end to which the amplified signal RF5 is supplied from the peak amplifier 52. The electrode 42b is electromagnetically coupled to the electrode 42a. The electrode 42b includes a first end to which the amplified signal RF4 is supplied from the carrier amplifier 51 and a second end that outputs the amplified signal RF6 to the output terminal 32 via the matching circuit 22.

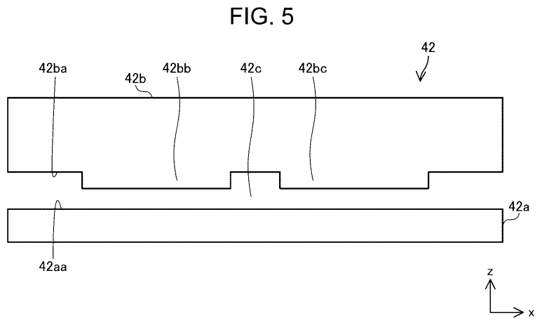

FIG. 4 is a plan view of the 90-degree coupler 42 viewed from above. FIG. 5 is a cross-sectional view taken along section line V-V in FIG. 4.

As illustrated in FIGS. 4 and 5, the electrodes 42a and 42b extend along the x-axis direction and face each other. In more detail, the electrode 42b is disposed above the electrode 42a. The electrode 42a has a facing surface 42aa, which is an upper surface facing the electrode 42b. The electrode 42b has a facing surface 42ba, which is a lower surface facing the electrode 42a. A dielectric layer 42c is provided between the facing surface 42aa and the facing surface 42ba. The width of the electrode 42b is less than the width of the electrode 42a.

The distance between the electrodes 42a and 42b is not constant. In the present embodiment, protrusions 42bb and 42bc are provided on the lower side of the electrode 42b. The protrusions 42bb and 42bc protrude downward. The distance between the electrodes 42a and 42b is shorter at the protrusions 42bb and 42bc. This makes it possible to increase the capacitance between the electrodes 42a and 42b at the protrusions 42bb and 42bc. The degree of electromagnetic coupling between the electrodes 42a and 42b can be adjusted by adjusting the positions, shapes, and sizes of the protrusions 42bb and 42bc. In particular, in a frequency band greater than or equal to 5 GHz, the length of the 90-degree coupler 42 is often short due to the relationship with the frequency band. Therefore, the impedance of the 90-degree coupler 42 can be adjusted by mainly adjusting the capacitance value. In other words, the impedance of the 90-degree coupler 42 can be more easily optimized by adjusting the capacitance between the electrodes 42a and 42b using the protrusions 42bb and 42bc.

As illustrated in FIG. 1, a control signal is supplied to the bias circuit 151 via a signal input terminal 171. The bias circuit 151 generates a bias based on the control signal and supplies the bias to the carrier amplifier 51. In the present embodiment, the carrier amplifier 51 operates in class A or class AB based on the bias supplied from the bias circuit 151.

The bias circuit 152 switches the bias point (operating point or operating class) of the peak amplifier 52 between a first bias point and a second bias point higher than the first bias point. For example, the bias circuit 152 supplies the peak amplifier 52 with a first bias or a second bias larger than the first bias.

In the present embodiment, the bias supplied to the peak amplifier 52 is switched between the first bias point and the second bias point based on modulation and coding scheme MCS) information indicating the modulation scheme and the coding rate of the signal RF1.

The MCS information indicates, for example, an MCS index defined by the WiFi communication standard. The MCS index represents a combination of a modulation scheme and a coding rate and, for example, takes a larger value as the maximum transmission speed increases.

The control circuit 162 receives MCS information from, for example, a communication device, such as an RFIC, and controls the bias circuit 152 based on the received MCS information. Specifically, the control circuit 162 controls the bias circuit 152 such that the bias point of the peak amplifier 52 is set to the second bias point when the MCS index indicated by the MCS information is greater than or equal to a first threshold. For example, when the MCS index indicated by the MCS information is greater than or equal to the first threshold, the control circuit 162 controls the bias circuit 152 to supply the second bias to the peak amplifier 52.

When the second bias is supplied to the peak amplifier 52, the power amplifier circuit 101 operates in the balanced mode. In this case, the bias point of the peak amplifier 52 is set to the second bias point, and the peak amplifier 52 operates in, for example, class AB. As a result, the power amplifier circuit 101 operates as a balanced amplifier.

On the other hand, when the MCS index indicated by the MCS information is less than the first threshold, the control circuit 162 controls the bias circuit 152 to supply the first bias to the peak amplifier 52.

When the first bias is supplied to the peak amplifier 52, the power amplifier circuit 101 operates in the Doherty mode. In this case, the bias point of the peak amplifier 52 is set to the first bias point, and the peak amplifier 52 operates in, for example, class C. As a result, the power amplifier circuit 101 operates as a Doherty amplifier.

Here, the control circuit 162 may perform control using multiple thresholds for the MCS index. Specifically, thresholds for the MCS index may include, in addition to the first threshold, an additional threshold that is greater than the first threshold. In this case, for example, the control circuit 162 controls the bias circuit 152 to supply the first bias to the peak amplifier 52 when the MCS index indicated by the MCS information is less than the first threshold. Also, the control circuit 162 controls the bias circuit 152 to supply the second bias to the peak amplifier 52 when the MCS index is greater than or equal to the first threshold and less than the additional threshold. Furthermore, the control circuit 162 controls the bias circuit 152 to supply a bias greater than the second bias to the peak amplifier 52 when the MCS index is greater than or equal to the additional threshold. Even when three or more thresholds for the MCS index are used, the control circuit 162 performs control in a manner similar to the case in which two thresholds are used.

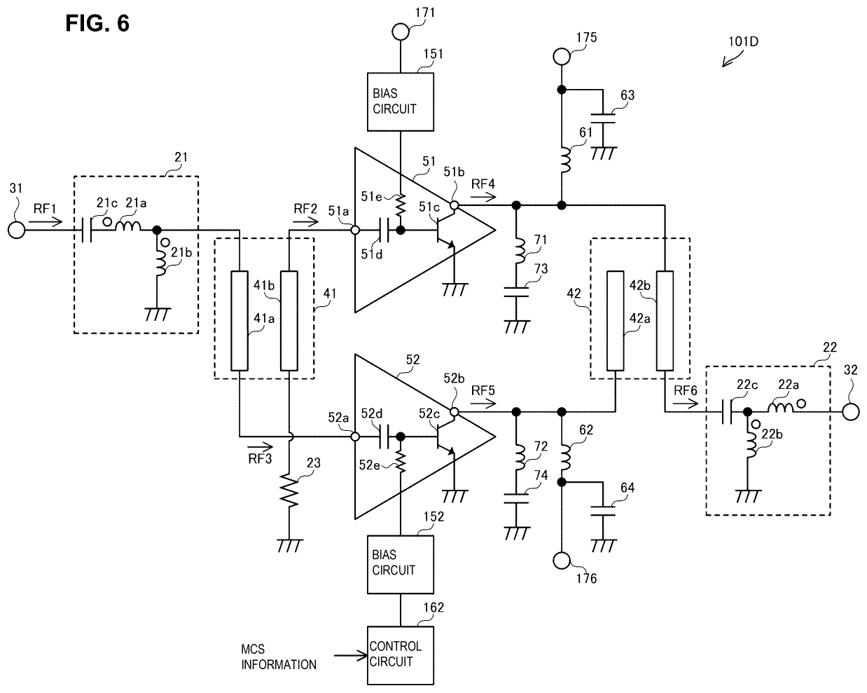

FIG. 6 is a circuit diagram of a power amplifier circuit 101D. As illustrated in FIG. 6, the power amplifier circuit 101D shows the details of the circuit diagram of the power amplifier circuit 101 illustrated in FIG. 1. Compared with the power amplifier circuit 101 illustrated in FIG. 1, the power amplifier circuit 101D additionally includes inductors 61, 62, 71, and 72 and capacitors 63, 64, 73, and 74.

The matching circuit 21 includes inductors 21a and 21b and a capacitor 21c. The matching circuit 22 includes inductors 22a and 22b and a capacitor 22c.

The carrier amplifier 51 includes an input terminal 51a, an output terminal 51b, an amplification transistor 51c, a capacitor 51d, and a resistor element 51e. The peak amplifier 52 includes an input terminal 52a, an output terminal 52b, an amplification transistor 52c, a capacitor 52d, and a resistor element 52e.

The capacitor 21c of the matching circuit 21 includes a first end connected to the input terminal 31, and a second end. The inductor 21a includes a first end connected to the second end of the capacitor 21c and a second end connected to the first end of the electrode 41a of the 90-degree coupler 41. The inductor 21b includes a first end connected to the second end of the inductor 21a and a second end connected to the ground.

The input terminal 51a of the carrier amplifier 51 is connected to the first end of the electrode 41b of the 90-degree coupler 41 and is supplied with the signal RF2. The output terminal 51b is connected to the first end of the electrode 42b of the 90-degree coupler 42 and supplies the amplified signal RF4.

The capacitor 51d includes a first end connected to the input terminal 51a, and a second end. The resistor element 51e includes a first end connected to the second end of the capacitor 51d, and a second end that is connected to the bias circuit 151 and is supplied with a bias.

The amplification transistor 51c includes a collector connected to the output terminal 51b, a base connected to the second end of the capacitor 51d, and an emitter connected to the ground.

The inductor 71 includes a first end connected to the output terminal 51b of the carrier amplifier 51 and a second end connected to the ground via the capacitor 73. In another configuration, the first end of the inductor 71 may be connected to the output terminal 51b of the carrier amplifier 51 via the capacitor 73, and the second end of the inductor 71 may be connected to the ground.

The inductor 61 includes a first end connected to a power supply voltage terminal 175 and a second end connected to the output terminal 51b of the carrier amplifier 51. The capacitor 63 includes a first end connected to the power supply voltage terminal 175 and a second end connected to the ground.

The input terminal 52a of the peak amplifier 52 is connected to the second end of the electrode 41a of the 90-degree coupler 41 and is supplied with the signal RF3. The output terminal 52b is connected to the second end of the electrode 42a of the 90-degree coupler 42 and supplies the amplified signal RF5.

The capacitor 52d includes a first end connected to the input terminal 52a, and a second end. The resistor element 52e includes a first end connected to the second end of the capacitor 52d, and a second end that is connected to the bias circuit 152 and is supplied with the first bias or the second bias.

The amplification transistor 52c includes a collector connected to the output terminal 52b, a base connected to the second end of the capacitor 52d, and an emitter connected to the ground.

The inductor 72 includes a first end connected to the output terminal 52b of the peak amplifier 52 and a second end connected to the ground via the capacitor 74. In another configuration, the first end of the inductor 72 may be connected to the output terminal 52b of the peak amplifier 52 via the capacitor 74, and the second end of the inductor 72 may be connected to the ground.

The inductor 62 includes a first end connected to a power supply voltage terminal 176 and a second end connected to the output terminal 52b of the peak amplifier 52. The capacitor 64 includes a first end connected to the power supply voltage terminal 176 and a second end connected to the ground.

The capacitor 22c of the matching circuit 22 includes a first end connected to the second end of the electrode 42b, and a second end. The inductor 22a includes a first end connected to the second end of the capacitor 22c and a second end connected to the output terminal 32. The inductor 22b includes a first end connected to the second end of the capacitor 22c and a second end connected to the ground.

In the configuration of the 90-degree coupler 41 illustrated in FIGS. 2 and 3, the electrode 41b includes the protrusions 41bb and 41bc. However, the present disclosure is not limited to this configuration. Alternatively, protrusions may be provided on the electrode 41a.

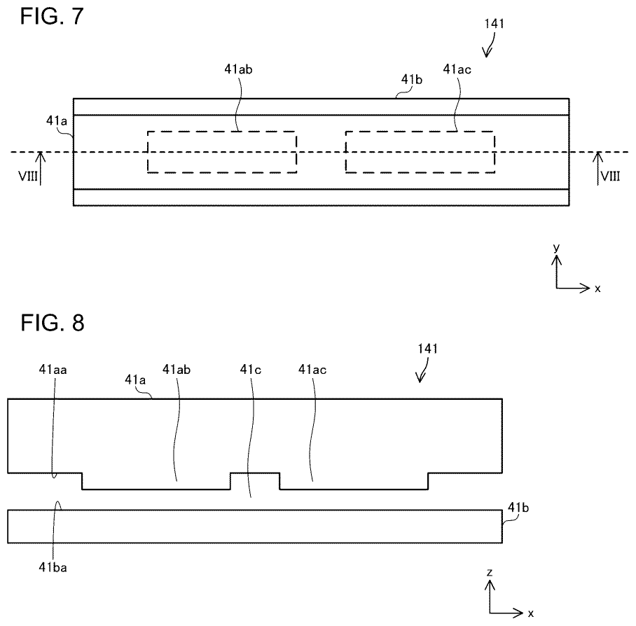

FIG. 7 is a plan view, viewed from above, of a 90-degree coupler 141 that is a variation of the 90-degree coupler 41. FIG. 8 is a cross-sectional view taken along section line VIII-VIII in FIG. 7.

As illustrated in FIGS. 7 and 8, the electrode 41a is disposed above the electrode 41b. The electrode 41a has a facing surface 41aa, which is a lower surface facing the electrode 41b. The electrode 41b has a facing surface 41ba, which is an upper surface facing the electrode 41a. The width of the electrode 41a is less than the width of the electrode 41b.

Protrusions 41ab and 41ac are provided on the lower side of the electrode 41a. The protrusions 41ab and 41ac protrude downward. The distance between the electrodes 41a and 41b is shorter at the protrusions 41ab and 41ac. This makes it possible to increase the capacitance between the electrodes 41a and 41b at the protrusions 41ab and 41ac.

### (Layout)

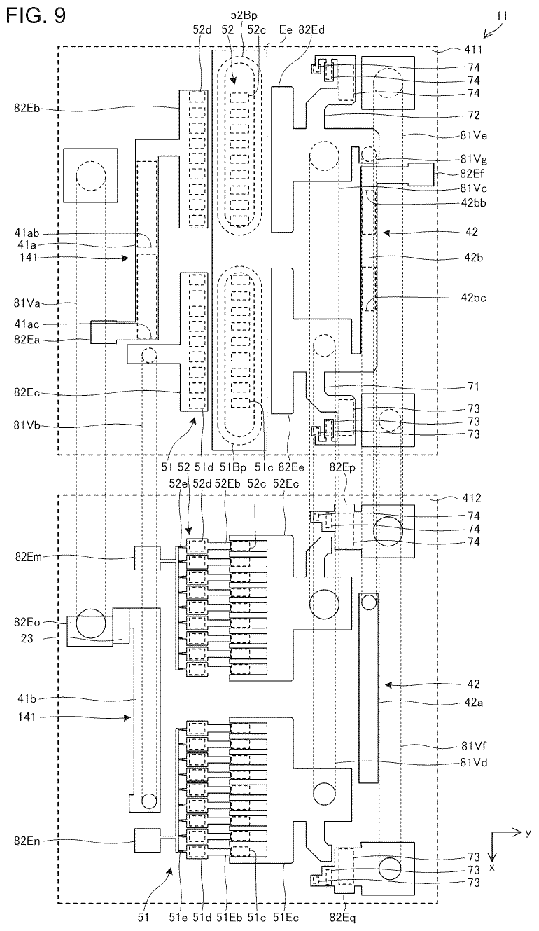

FIG. 9 is a diagram schematically illustrating cross-sections, which are parallel to the xy plane, of the semiconductor chip 11 on which the power amplifier circuit 101D is formed.

As illustrated in FIG. 9, the semiconductor chip 11 includes conductive layers 411 and 412. For example, the conductive layers 411 and 412 are arranged in this order from the upper side toward the lower side.

A dielectric layer 41c or 42c (not shown) is provided between the conductive layers 411 and 412. Vias 81Va, 81Vb, 81Vc, 81Vd, 81Ve, 81Vf, and 81Vg, which extend along the stacking direction, are formed in the dielectric layer 41c or 42c.

For example, a ground layer (not shown) with a ground potential is provided above the conductive layer 411. A dielectric layer (not shown) is provided between the conductive layer 411 and the ground layer.

The electrode 41a of the 90-degree coupler 141, the electrode 42b of the 90-degree coupler 42, an emitter electrode Ee, and electrodes 82Ea, 82Eb, 82Ec, 82Ed, 82Ee, and 82Ef are formed on or in the conductive layer 411.

The electrode 41b of the 90-degree coupler 141, the electrode 42a of the 90-degree coupler 42, nine base electrodes 51Eb, a collector electrode 51Ec, nine resistor elements 51e, nine base electrodes 52Eb, a collector electrode 52Ec, nine resistor elements 52e, and electrodes 82Em, 82En, 82Eo, 82Ep, and 82Eq are formed on or in the conductive layer 412.

Each of the carrier amplifier 51 and the peak amplifier 52 is, for example, a multi-finger transistor in which multiple unit transistors (hereafter may be referred to as “fingers”) are electrically connected in parallel with each other.

In the present embodiment, the carrier amplifier 51 includes nine sets of the amplification transistor 51c, the capacitor 51d, and the resistor element 51e. The peak amplifier 52 includes nine sets of the amplification transistor 52c, the capacitor 52d, and the resistor element 52e.

When the semiconductor chip 11 is viewed from above, the nine amplification transistors 51c are arranged along the x-axis. The nine amplification transistors 52c are disposed on the negative x-axis side of the nine amplification transistors 51c and are arranged along the axis along which the nine amplification transistors 51c are arranged.

On or in the conductive layer 412, nine base electrodes 51Eb are provided on the negative y-axis side of the corresponding nine amplification transistors 51c. The bases of the nine amplification transistors 51c are electrically connected to the corresponding nine base electrodes 51Eb.

The first end of each of the nine resistor elements 51e is electrically connected to the negative y-axis side of the corresponding one of the nine base electrodes 51Eb. The second end of each of the nine resistor elements 51e is electrically connected to the bias circuit 151 via the electrode 82En.

The nine capacitors 51d are formed on the upper side of the corresponding nine base electrodes 51Eb. The second ends, i.e., the lower electrodes, of the nine capacitors 51d are electrically connected to the upper surfaces of the corresponding nine base electrodes 51Eb. The first ends, i.e., the upper electrodes, of the nine capacitors 51d are electrically connected to an electrode 82Ec formed on or in the conductive layer 411.

On or in the conductive layer 412, the collector electrode 51Ec is provided on the positive y-axis side of the nine amplification transistors 51c. The collectors of the nine amplification transistors 51c are electrically connected to the electrode 82Ee on or in the conductive layer 411 through the collector electrode 51Ec and the via 81Vd.

The nine base electrodes 52Eb are provided on the negative y-axis side of the corresponding nine amplification transistors 52c. The bases of the nine amplification transistors 52c are electrically connected to the corresponding nine base electrodes 52Eb.

The first end of each of the nine resistor elements 52e is electrically connected to the negative y-axis side of the corresponding one of the nine base electrodes 52Eb. The second end of each of the nine resistor elements 52e is electrically connected to the bias circuit 152 via the electrode 82Em.

The nine capacitors 52d are formed on the upper side of the corresponding nine base electrodes 52Eb. The second ends, i.e., the lower electrodes, of the nine capacitors 52d are electrically connected to the upper surfaces of the corresponding nine base electrodes 52Eb. The first ends, i.e., the upper electrodes, of the nine capacitors 52d are electrically connected to the electrode 82Eb formed on or in the conductive layer 411.

On or in the conductive layer 412, the collector electrode 52Ec is provided on the positive y-axis side of the nine amplification transistors 52c. The collectors of the nine amplification transistors 52c are electrically connected to the electrode 82Ed on or in the conductive layer 411 through the collector electrode 52Ec and the via 81Vc.

On or in the conductive layer 411, the emitter electrode Ee is formed to extend along the axis along which the nine amplification transistors 51c and the nine amplification transistors 52c are arranged.

When the semiconductor chip 11 is viewed from above, the nine amplification transistors 51c and the nine amplification transistors 52c overlap the emitter electrode Ee.

The emitters of the nine amplification transistors 51c and the emitters of the nine amplification transistors 52c are electrically connected to the emitter electrode Ee.

The upper surface of the emitter electrode Ee is electrically connected to the ground layer via bumps 51Bp and 52Bp. When the semiconductor chip 11 is viewed from above, the nine amplification transistors 51c are disposed inside of the contour of the bump 51Bp. Also, when the semiconductor chip 11 is viewed from above, the nine amplification transistors 52c are disposed inside of the contour of the bump 52Bp.

The 90-degree coupler 141 is provided on the negative y-axis side of the carrier amplifier 51 and the peak amplifier 52. On or in the conductive layer 411, the first end of the electrode 41a of the 90-degree coupler 141 is disposed on the positive x-axis side and is electrically connected to the matching circuit 21 via the electrode 82Ea. The second end of the electrode 41a is disposed on the negative x-axis side and is electrically connected to the electrode 82Eb.

On or in the conductive layer 412, the first end of the electrode 41b of the 90-degree coupler 141 is disposed on the positive x-axis side and is electrically connected to the electrode 82Ec through the via 81Vb. The second end of the electrode 41b is disposed on the negative x-axis side and is electrically connected to the ground through the resistor element 23, the electrode 82Eo, and the via 81Va.

The 90-degree coupler 42 is provided on the positive y-axis side of the carrier amplifier 51 and the peak amplifier 52. On or in the conductive layer 411, the first end of the electrode 42b of the 90-degree coupler 42 is disposed on the positive x-axis side and is electrically connected to the electrode 82Ee. The second end of the electrode 42b is disposed on the negative x-axis side and is electrically connected to the matching circuit 22 through the electrode 82Ef.

On or in the conductive layer 412, the first end of the electrode 42a of the 90-degree coupler 42 is disposed on the positive x-axis side and is open. The second end of the electrode 42a is disposed on the negative x-axis side and is electrically connected to the electrode 82Ed through the via 81Vg.

The inductor 71 and the capacitor 73 are formed on the positive x-axis side of the 90-degree coupler 42. The inductor 72 and the capacitor 74 are formed on the negative x-axis side of the 90-degree coupler 42.

### (Effects)

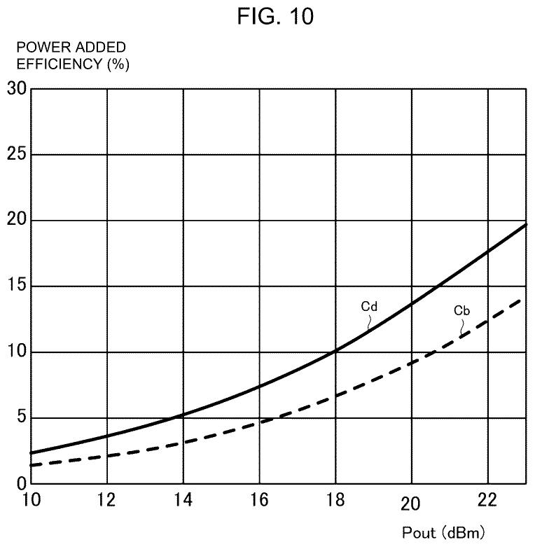

FIG. 10 is a graph showing an example of the efficiency characteristic of the power amplifier circuit 101. The vertical axis indicates the power added efficiency of the power amplifier circuit 101, which is expressed in “%”. The horizontal axis indicates output power Pout expressed in “dBm”.

In FIG. 10, a curve Cd and a curve Cb correspond to the Doherty mode and the balanced mode, respectively. The power load efficiency of the power amplifier circuit 101 in the Doherty mode is higher than the power load efficiency of the power amplifier circuit 101 in the balanced mode.

That is, when the MCS index is less than the first threshold, the power amplifier circuit 101 operates in the Doherty mode, and the current consumption in the power amplifier circuit 101 can be reduced. In a low MCS rate mode (Doherty mode), in which the MCS index is less than the first threshold, a modulated signal is often relatively simple, and the required linearity is not very high. Therefore, in the low MCS rate mode, it is possible to satisfy distortion characteristics up to a relatively high power level, and the power required for the power amplifier circuit tends to be larger compared with a high MCS rate mode (balanced mode) in which the MCS index is greater than or equal to the first threshold. Accordingly, causing the power amplifier circuit 101 to operate in the Doherty mode makes it possible to reduce the current consumption of the power amplifier circuit 101 and thereby maintain good characteristics.

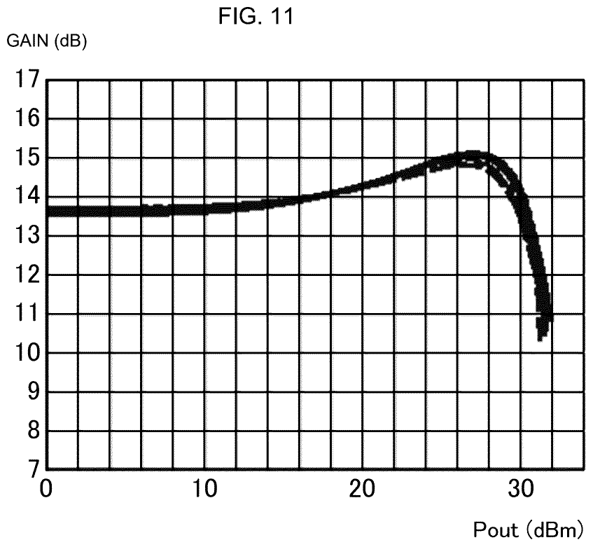

FIG. 11 is a graph showing an example of load variation tolerance of the power amplifier circuit 101 in the balanced mode. The vertical axis indicates the gain of the power amplifier circuit 101, which is expressed in dB. The horizontal axis indicates the output power Pout expressed in dBm.

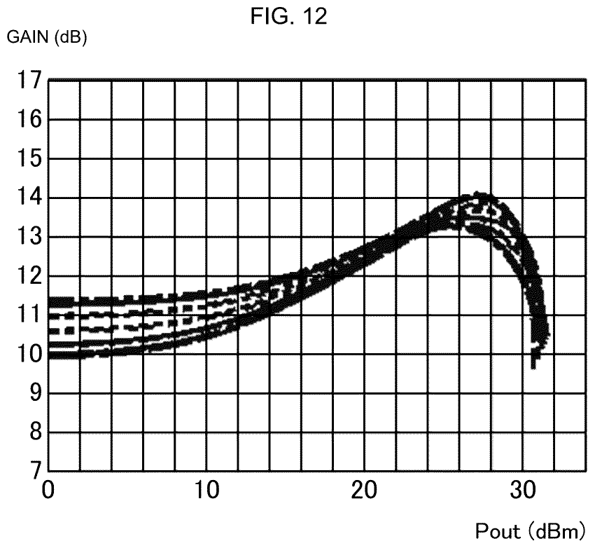

FIG. 12 is a graph showing an example of load variation tolerance of the power amplifier circuit 101 in the Doherty mode. The axis labels in FIG. 12 are the same as those in FIG. 11.

Each of FIGS. 11 and 12 shows the variation in gain that is observed when the load downstream of the output terminal 32 is varied such that the phase changes at a voltage standing wave ratio (VSWR) of 1:2.

The gain variation resulting from the load variation in the balanced mode is less than the gain variation resulting from the load variation in the Doherty mode.

That is, when the MCS index is greater than or equal to the first threshold, the power amplifier circuit 101 operates in the balanced mode, and the load variation characteristic of the power amplifier circuit 101 can be improved. Also, because the peak amplifier 52 operates in class AB, the linearity of the amplification characteristic of the power amplifier circuit 101 can be improved. In the high MCS rate mode in which the MCS index is greater than or equal to the first threshold, the modulated signal is often relatively complex, and the required linearity also tends to increase. Therefore, in the high MCS rate mode, the distortion characteristics can only be satisfied at a relatively low power level, and the power required for the power amplifier circuit tends to become smaller compared with the low MCS rate mode in which the MCS index is less than the first threshold. Accordingly, causing the power amplifier circuit 101 to operate in the balanced mode makes it possible to improve the linearity of the amplification characteristic of the power amplifier circuit 101 and thereby maintain good characteristics.

### Second Embodiment

A power amplifier circuit 102 according to a second embodiment is described. In the second and subsequent embodiments, descriptions of features that are the same as those in the first embodiment are omitted, and only the differences are described. In particular, the description of the same effect provided by the same feature is not repeated for each embodiment.

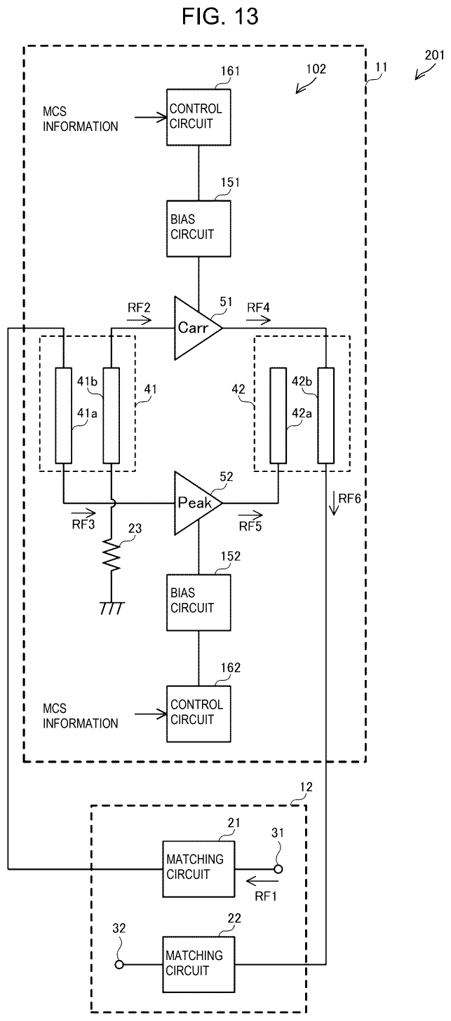

FIG. 13 is a circuit diagram of the power amplifier circuit 102. As illustrated in FIG. 13, the power amplifier circuit 102 according to the second embodiment differs from the power amplifier circuit 101 according to the first embodiment in that the power amplifier circuit 102 additionally includes a control circuit 161.

The bias circuit 151 switches the bias point (operating point or operating class) of the carrier amplifier 51 between a third bias point and a fourth bias point higher than the third bias point. For example, the bias circuit 151 supplies either a third bias or a fourth bias greater than the third bias to the carrier amplifier 51.

In the present embodiment, the bias supplied to the carrier amplifier 51 is switched between the third bias point and the fourth bias point based on the MCS information.

For example, the control circuit 161 receives MCS information from a communication apparatus and controls the bias circuit 151 based on the received MCS information. Specifically, the control circuit 161 controls the bias circuit 151 such that the bias point of the carrier amplifier 51 is set to the fourth bias point when the MCS index indicated by the MCS information is greater than or equal to the second threshold. For example, the control circuit 161 controls the bias circuit 151 such that the fourth bias is supplied to the carrier amplifier 51 when the MCS index indicated by the MCS information is greater than or equal to the second threshold. Here, the second threshold may be the same as or different from the first threshold described above.

When the fourth bias is supplied to the carrier amplifier 51, the bias point of the carrier amplifier 51 is set to the fourth bias point, and the carrier amplifier 51 operates in, for example, class AB that is closer to class A.

On the other hand, the control circuit 161 controls the bias circuit 151 such that the third bias is supplied to the carrier amplifier 51 when the MCS index indicated by the MCS information is less than the second threshold.

When the third bias is supplied to the carrier amplifier 51, the bias point of the carrier amplifier 51 is set to the third bias point, and the carrier amplifier 51 operates in, for example, class AB that is closer to class B.

Here, the control circuit 161 may perform control using multiple thresholds for the MCS index. In this case, the control circuit 161 performs control similar to the control performed by the control circuit 162.

### Third Embodiment

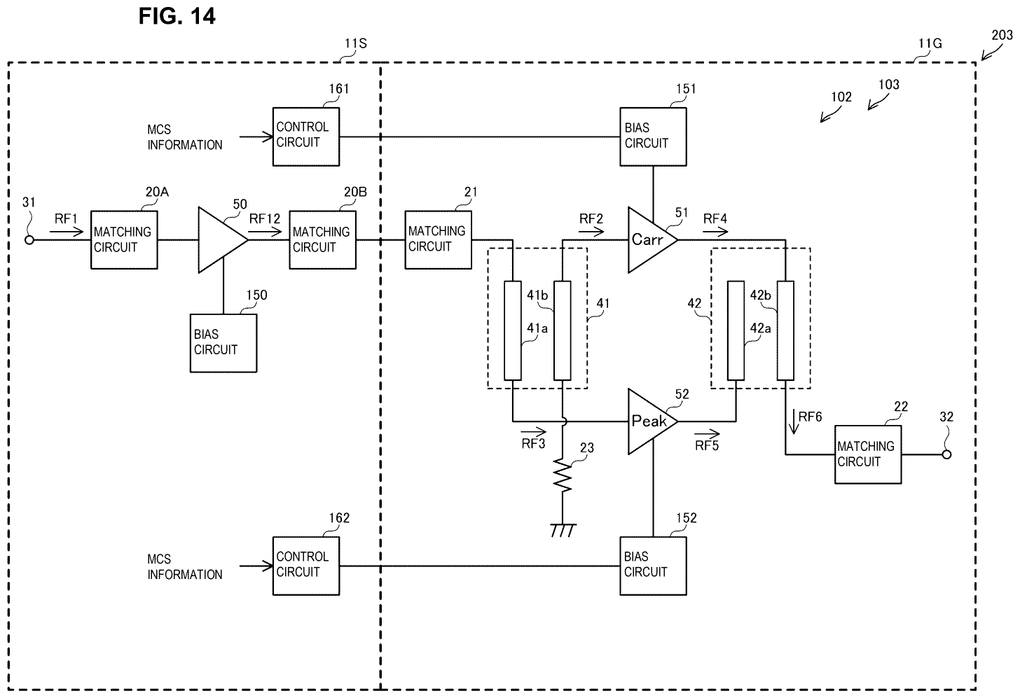

FIG. 14 is a circuit diagram of a power amplifier circuit 103 formed in a power amplification device 203. As illustrated in FIG. 14, the power amplification device 203 according to a third embodiment differs from the power amplification device 201 according to the first embodiment in that the power amplifier circuit is formed across a first substrate of a compound semiconductor and a second substrate of a single-element semiconductor.

In the present embodiment, the first substrate is, for example, a GaAs semiconductor chip 11G, which is formed of a compound semiconductor (hereafter may be referred to as a first compound semiconductor) including gallium and arsenic. The second substrate is, for example, an Si semiconductor chip 11S, which is formed of a single-element semiconductor including silicon.

The power amplifier circuit 103 is formed in the power amplification device 203. Compared with the power amplifier circuit 102 (see FIG. 13) formed in the power amplification device 201, the power amplifier circuit 103 additionally includes matching circuits 20A and 20B, a driver stage amplifier 50, and a bias circuit 150.

The matching circuits 20A and 20B, the driver stage amplifier 50, the bias circuit 150, and the control circuits 161 and 162 of the power amplifier circuit 103 are formed on the Si semiconductor chip 11S.

The matching circuits 21 and 22, the 90-degree couplers 41 and 42, the carrier amplifier 51, the peak amplifier 52, and the bias circuits 151 and 152 are formed on the GaAs semiconductor chip 11G.

The matching circuit 20A of the power amplifier circuit 103 is disposed between the input terminal 31 and the driver stage amplifier 50 and provides impedance matching between the driver stage amplifier 50 and a circuit (not shown) provided upstream of the input terminal 31.

The driver stage amplifier 50 amplifies the signal RF1 (input signal) supplied from the input terminal 31 via the matching circuit 20A and outputs the amplified signal RF12 (first signal). The driver stage amplifier 50 includes, for example, a field-effect transistor. Alternatively, the driver stage amplifier 50 may be configured to include a bipolar transistor. The bias circuit 150 generates a bias and supplies the bias to the driver stage amplifier 50.

The matching circuit 20B is disposed between the driver stage amplifier 50 and the matching circuit 21 and provides impedance matching between the driver stage amplifier 50 and the matching circuit 21.

The 90-degree coupler 41 splits the amplified signal RF12, which is supplied from the driver stage amplifier 50 via the matching circuits 20B and 21, into the signal RF2 and the signal RF3 that is out of phase with the signal RF2.

### (Effects)

The field-effect transistor included in the driver stage amplifier 50 is sensitive to changes in the drain side impedance. In the power amplification device 203, the 90-degree coupler 41 is provided downstream of the driver stage amplifier 50. This makes it possible to set the phase difference between the reflected wave from the carrier amplifier 51 and the reflected wave from the peak amplifier 52 at substantially 180°.

This in turn makes it possible to reduce the power of the reflected waves and thereby achieve the impedance matching between the driver stage amplifier 50 and the combination of the carrier amplifier 51 and the peak amplifier 52 with a simple configuration.

Because the bipolar transistor included in each of the carrier amplifier 51 and the peak amplifier 52 is sensitive to changes in the input-side voltage, the control of the input-side impedance is important.

Because the 90-degree coupler 41 is provided upstream of the carrier amplifier 51 and the peak amplifier 52, when one of the impedance of the driver stage amplifier 50 viewed from the carrier amplifier 51 and the impedance of the driver stage amplifier 50 viewed from the peak amplifier 52 increases, the other one decreases.

For this reason, when the drain voltage of the driver stage amplifier 50 dynamically changes, the carrier amplifier 51 and the peak amplifier 52 function to cancel out the change.

This makes it possible to achieve the impedance matching between the Si semiconductor chip 11S and the GaAs semiconductor chip 11G with a simple configuration and thereby makes it possible to provide the power amplification device 203 that can amplify signals in a wide frequency band.

In the present embodiment, the Si semiconductor chip 11S is a single-element semiconductor including silicon. However, the present disclosure is not limited to this example. The Si semiconductor chip 11S may instead be a single-element semiconductor including an element other than silicon. Also, a second substrate comprised of a second compound semiconductor may be provided instead of the Si semiconductor chip 11S. Here, the elements included in the second compound semiconductor are different from the elements, i.e., gallium and arsenic, included in the first compound semiconductor.

In the power amplifier circuit 101, the second bias is supplied to the peak amplifier 52 when the MCS index for the signal RF1 is greater than or equal to the first threshold, and the first bias is supplied to the peak amplifier 52 when the MCS index is less than the first threshold. However, the present disclosure is not limited to this example. As another example, the power amplifier circuit 101 may be configured such that the second bias is supplied to the peak amplifier 52 (or the bias point of the peak amplifier 52 is changed to the second bias point) when the MCS index is greater than the first threshold, and the first bias is supplied to the peak amplifier 52 (or the bias point of the peak amplifier 52 is changed to the first bias point) when the MCS index is less than or equal to the first threshold.

Also, in the power amplifier circuit 102, the fourth bias is supplied to the carrier amplifier 51 when the MCS index for the signal RF1 is greater than or equal to the second threshold, and the third bias is supplied to the carrier amplifier 51 when the MCS index is less than the second threshold. However, the present disclosure is not limited to this example. As another example, the power amplifier circuit 102 may be configured such that the fourth bias is supplied to the carrier amplifier 51 (or the bias point of the carrier amplifier 51 is changed to the fourth bias point) when the MCS index is greater than the second threshold, and the third bias is supplied to the carrier amplifier 51 (or the bias point of the carrier amplifier 51 is changed to the third bias point) when the MCS index is less than or equal to the second threshold.

In the example of the configuration of the power amplifier circuit 101 described above, the electrodes 41a and 41b of the 90-degree coupler 41 overlap each other when viewed from above. However, the present disclosure is not limited to this example. Alternatively, the electrodes 41a and 41b may be arranged so as not to overlap each other when viewed from above but may be arranged in the xy plane.

In the example of the configuration of the power amplifier circuit 101 described above, the electrodes 42a and 42b of the 90-degree coupler 42 overlap each other when viewed from above. However, the present disclosure is not limited to this example. Alternatively, the electrodes 42a and 42b may be arranged so as not to overlap each other when viewed from above but may be arranged in the xy plane.

In the example of the configuration of the power amplifier circuit 101 described above, the power amplifier circuit 101 is formed on the semiconductor chip 11, and the matching circuits 21 and 22 are formed on the printed circuit board 12. However, the present disclosure is not limited to this example. Alternatively, at least one of the matching circuits 21 and 22 may be formed on the semiconductor chip 11. Here, if the matching circuit 21 is formed on the semiconductor chip 11, the electrodes may become thinner, and the size of the inductors may become smaller. Particularly, in a frequency band greater than or equal to 5 GHz, this may increase the loss of signals passing through the matching circuit 21. For this reason, the matching circuit 21 may be formed on the printed circuit board 12. The above descriptions related to the matching circuit 21 are also applicable to the matching circuit 22.

Embodiments of the present disclosure are described above. In each of the power amplifier circuits 101 and 102, the 90-degree coupler 41 splits the signal RF1 into the signal RF2 and the signal RF3 that is out of phase with the signal RF2. The carrier amplifier 51 amplifies the signal RF2 and outputs the amplified signal RF4. The peak amplifier 52 amplifies the signal RF3 and outputs the amplified signal RF5. The 90-degree coupler 42 combines the amplified signal RF4 with the amplified signal RF5 to generate the amplified signal RF6. The bias circuit 152 switches the bias point of the peak amplifier 52 between the first bias point and the second bias point, which is higher than the first bias point.

With the above configuration in which the 90-degree couplers 41 and 42 are provided instead of a λ/4 line with a large size, the circuit size of the power amplifier circuit 101 can be reduced. Also, with the configuration in which the bias point of the peak amplifier 52 is switched between the first bias point and the second bias point, it is possible to cause each of the power amplifier circuits 101 and 102 to operate, for example, either as a Doherty amplifier or a balanced amplifier. This makes it possible to provide a power amplifier circuit and a power amplification device each of which has a small circuit size and is capable of changing the bias point of a peak amplifier.

In each of the power amplifier circuits 101 and 102, the signal RF1 is a modulated signal. Also, the bias point is switched between the first bias point and the second bias point based on MCS information indicating the modulation scheme and the coding rate of the signal RF1.

With this configuration, when a complex modulation scheme and a high coding rate, which require the linearity of the amplification characteristic of the power amplifier circuit 101, are used, it is possible to cause the power amplifier circuit 101 to operate as a balanced amplifier by setting the bias point of the peak amplifier 52 to the second bias point. Also, when the linearity of the amplification characteristic required for the power amplifier circuit 101 is low, and a simple modulation scheme and a low coding rate are mainly used up to the high output power, it is possible to cause the power amplifier circuit 101 to operate as a Doherty amplifier by setting the bias point of the peak amplifier 52 to the first bias point.

Also, in the power amplifier circuits 101 and 102, MCS information indicates an MCS index. When the MCS index is greater than or equal to the first threshold, the bias point of the peak amplifier 52 is set to the second bias point; and when the MCS index is less than the first threshold, the bias point of the peak amplifier 52 is set to the first bias point.

Thus, with the configuration in which the bias point of the peak amplifier 52 is switched between the first bias point and the second bias point by using the first threshold and the MCS index that increases as the modulation scheme becomes more complex and also increases as the coding rate becomes higher, it is possible to appropriately and easily switch the operation mode of the power amplifier circuit 101 between the balanced amplifier and the Doherty amplifier.

In the power amplifier circuit 102, the bias circuit 151 switches the bias point of the carrier amplifier 51 between the third bias point and the fourth bias point, which is higher than the third bias point.

With the configuration in which the bias point of the carrier amplifier 51 is switched between the third bias point and the fourth bias point, it is possible to cause the carrier amplifier 51 to operate in either class AB closer to class B or class AB closer to class A.

In each of the power amplifier circuits 101 and 102, the first signal is a modulated signal. When the MCS index for the signal RF1 is greater than or equal to the second threshold, the bias point of the carrier amplifier 51 is set to the fourth bias point; and when the MCS index is less than the second threshold, the bias point of the carrier amplifier 51 is set to the third bias point.

This configuration makes it possible to appropriately and easily switch the bias point of the carrier amplifier 51 according to the MCS index. This in turn makes it possible to cause the power amplifier circuit 101 to properly operate as a balanced amplifier or a Doherty amplifier.

In the power amplifier circuits 101 and 102, the frequency of the signal RF1 is greater than or equal to 5 GHz.

With this configuration, when a modulation scheme and a coding rate in a WiFi communication standard for a frequency band greater than or equal to 5 GHz are used, the signal RF1 can be appropriately amplified.

In the power amplifier circuits 101 and 102, the 90-degree coupler 41 includes the electrodes 41a and 41b. The electrode 41a includes the first end to which the signal RF1 is supplied and the second end that outputs the signal RF3. The electrode 41b is electromagnetically coupled to the electrode 41a and includes the first end that outputs the signal RF2 and the second end to which a predetermined potential is supplied. The electrodes 41a and 41b face each other. Also, the distance between the electrodes 41a and 41b is not constant.

This configuration makes it possible to adjust the capacitance between the electrodes 41a and 41b and thereby makes it possible to appropriately adjust the splitting characteristic of the 90-degree coupler 41.

Also, in the power amplifier circuits 101 and 102, the 90-degree coupler 42 includes the electrodes 42a and 42b. The electrode 42a includes the first end that is open and the second end to which the amplified signal RF5 is supplied. The electrode 42b is electromagnetically coupled to the electrode 42a and includes the first end to which the amplified signal RF4 is supplied and the second end that outputs the amplified signal RF6. The electrodes 42a and 42b face each other. Also, the distance between the electrodes 42a and 42b is not constant.

This configuration makes it possible to adjust the capacitance between the electrodes 42a and 42b and thereby makes it possible to appropriately adjust the combining characteristics of the 90-degree coupler 42.

In the power amplification device 201, the power amplifier circuit 101 or 102 is formed on the semiconductor chip 11. Also, the semiconductor chip 11 is mounted on the printed circuit board 12, and the matching circuits 21 and 22, which are disposed, respectively, upstream and downstream of the power amplifier circuit 101 or 102, are formed on the printed circuit board 12.

Compared with the configuration in which the matching circuits 21 and 22 are formed on the semiconductor chip 11, the above configuration, in which the matching circuits 21 and 22 are formed on the printed circuit board 12 on which large inductors can be easily formed using thick electrodes, makes it possible to reduce the loss of signals passing through the matching circuits 21 and 22.

In the power amplification device 203, the power amplifier circuit 101 or 102 is formed on the GaAs semiconductor chip 11G. The driver stage amplifier 50, which amplifies the signal RF1 and outputs the amplified signal RF12, is formed on the Si semiconductor chip 11S or the second substrate comprised of the second compound semiconductor. The GaAs semiconductor chip 11G is different from the second compound semiconductor.

The driver stage amplifier 50, which is formed on the Si semiconductor chip 11S or the second substrate comprised of the second compound semiconductor, is sensitive to the load-side impedance. However, with the configuration in which the 90-degree coupler 41 is provided between the driver stage amplifier 50 and the combination of the carrier amplifier 51 and the peak amplifier 52, it is possible to easily achieve the impedance matching between the driver stage amplifier 50 and the combination of the carrier amplifier 51 and the peak amplifier 52. The carrier amplifier 51 and the peak amplifier 52 are sensitive to changes in the input-side voltage. However, with the configuration in which the 90-degree coupler 41 is provided upstream of these amplifiers, when the drain voltage of the driver stage amplifier 50 dynamically changes, the carrier amplifier 51 and the peak amplifier 52 can be caused to operate to cancel out the change. That is, the above configuration makes it possible to achieve impedance matching between the Si semiconductor chip 11S or the second substrate comprised of the second compound semiconductor and the GaAs semiconductor chip 11G with a simple configuration and thereby makes it possible to provide the power amplification device 203 that can amplify signals in a wide frequency band.

The above-described embodiments are intended to facilitate the understanding of the present disclosure and are not intended to limit the interpretation of the present disclosure. The present disclosure may be modified or improved without departing from the spirit of the present disclosure, and the present disclosure may include its equivalents. That is, any embodiment implemented by a person skilled in the art by changing any of the above embodiments may be included in the scope of the present disclosure as long as the implemented embodiment includes features of the present disclosure. For example, elements in the embodiments and their arrangements, materials, conditions, shapes, sizes, etc., are not limited to the examples described in the embodiments and can be modified as necessary. Needless to say, the embodiments are examples. Partial substitutions and combinations of components in different embodiments may be made, and resulting embodiments are also included in the scope of the present disclosure as long as those embodiments include features of the present disclosure.
<1> A power amplifier circuit includes a first coupler that splits a first signal into a second signal and a third signal that is out of phase with the second signal; a carrier amplifier that amplifies the second signal to output a first amplified signal; a peak amplifier that amplifies the third signal to output a second amplified signal; a second coupler that generates a third amplified signal by combining the first amplified signal and the second amplified signal; and a first bias circuit that switches the bias point of the peak amplifier between a first bias point and a second bias point higher than the first bias point.
<2> In the power amplifier circuit described in <1>, the first signal is a modulated signal, and the bias point is switched between the first bias point and the second bias point based on modulation and coding scheme (MCS) information indicating a modulation scheme and a coding rate of the first signal.
<3> In the power amplifier circuit described in <2>, the MCS information indicates an MCS index, the bias point of the peak amplifier is set to the second bias point when the MCS index is greater than or equal to a first threshold, and the bias point of the peak amplifier is set to the first bias point when the MCS index is less than the first threshold.
<4> The power amplifier circuit described in any one of <1> to <3> further includes a second bias circuit that switches the bias point of the carrier amplifier between a third bias point and a fourth bias point higher than the third bias point.
<5> In the power amplifier circuit described in <4>, the first signal is a modulated signal, the bias point of the carrier amplifier is set to the fourth bias point when the MCS index for the first signal is greater than or equal to a second threshold, and the bias point of the carrier amplifier is set to the third bias point when the MCS index is less than the second threshold.
<6> In the power amplifier circuit described in any one of <1> to <5>, the frequency of the first signal is greater than or equal to 5 GHz.
<7> In the power amplifier circuit described in any one of <1> to <6>, the first coupler includes a first electrode including a first end to which the first signal is supplied and a second end that outputs the third signal; and a second electrode that is electromagnetically coupled to the first electrode and includes a first end that outputs the second signal and a second end to which a predetermined potential is supplied. The first electrode and the second electrode face each other, and the distance between the first electrode and the second electrode is not constant.
<8> In the power amplifier circuit described in any one of <1> to <7>, the second coupler includes a third electrode including an open first end and a second end to which the second amplified signal is supplied, and a fourth electrode that is electromagnetically coupled to the third electrode and includes a first end to which the first amplified signal is supplied and a second end that outputs the third amplified signal. The third electrode and the fourth electrode face each other; and the distance between the third electrode and the fourth electrode is not constant.
<9> A power amplification device includes a semiconductor chip on which the power amplifier circuit described in any one of <1> to <8> is formed, and a substrate on which the semiconductor chip is mounted and a matching circuit is formed upstream or downstream of the power amplifier circuit.
<10> A power amplification device includes a first substrate that is comprised of a first compound semiconductor and on which the power amplifier circuit described in any one of <1> to <8> is formed, and a second substrate that is comprised of a single-element semiconductor or a second compound semiconductor and on which an amplifier, which amplifies an input signal to output the first signal, is formed. The first compound semiconductor is different from the second compound semiconductor.
11 semiconductor chip
11G GaAs semiconductor chip
11S Si semiconductor chip
12 printed circuit board
20A, 20B, 21, 22 matching circuit
21a, 21b, 22a, 22b inductor
21c, 22c capacitor
23 resistor element
31 input terminal
32 output terminal
41, 141 90-degree coupler
41A, 41B electrode
41aa, 41ba facing surface
41ab, 41ac, 41bb, 41bc protrusion
42 90-degree coupler
42a, 42b electrode
42aa, 42ba facing surface
42bb, 42bc protrusion
50 driver stage amplifier
51 carrier amplifier
51a input terminal
51b output terminal
51c amplification transistor
51D capacitor
51e resistor element
52 peak amplifier
52a input terminal
52b output terminal
52c amplification transistor
52D capacitor
52e resistor element
101, 101D, 102, 103 power amplifier circuit
150, 151, 152 bias circuit
161, 162 control circuit
171 signal input terminal
201, 203 power amplification device
411, 412 conductive layer

1. A power amplifier circuit comprising:
a first coupler configured to split a first signal into a second signal and a third signal that is out of phase with the second signal;
a carrier amplifier configured to amplify the second signal and to output a first amplified signal;
a peak amplifier configured to amplify the third signal and to output a second amplified signal;
a second coupler configured to generate a third amplified signal by combining the first amplified signal and the second amplified signal; and
a first bias circuit configured to switch a bias point of the peak amplifier between a first bias point and a second bias point higher than the first bias point.

2. The power amplifier circuit according to claim 1,
wherein the first signal is a modulated signal, and
wherein the bias point is switched between the first bias point and the second bias point based on modulation and coding scheme (MCS) information indicating a modulation scheme and a coding rate of the first signal.

3. The power amplifier circuit according to claim 2,
wherein the MCS information indicates an MCS index,
wherein the bias point of the peak amplifier is set to the second bias point when the MCS index is greater than or equal to a first threshold, and
wherein the bias point of the peak amplifier is set to the first bias point when the MCS index is less than the first threshold.

4. The power amplifier circuit according to claim 1, further comprising:
a second bias circuit configured to switch a bias point of the carrier amplifier between a third bias point and a fourth bias point higher than the third bias point.

5. The power amplifier circuit according to claim 4,
wherein the first signal is a modulated signal,
wherein the bias point of the carrier amplifier is set to the fourth bias point when the MCS index for the first signal is greater than or equal to a second threshold, and
wherein the bias point of the carrier amplifier is set to the third bias point when the MCS index is less than the second threshold.

6. The power amplifier circuit according to claim 1, wherein the frequency of the first signal is greater than or equal to 5 GHz.

7. The power amplifier circuit according to claim 1,
wherein the first coupler comprises:
a first electrode having a first end to which the first signal is supplied and a second end from which the third signal is output; and
a second electrode that is electromagnetically coupled to the first electrode and that has a first end from which the second signal is output and a second end to which a predetermined potential is supplied,
wherein the first electrode and the second electrode face each other, and
wherein a distance between the first electrode and the second electrode is not constant.

8. The power amplifier circuit according to claim 1,
wherein the second coupler comprises:
a third electrode having an open first end and a second end to which the second amplified signal is supplied; and
a fourth electrode that is electromagnetically coupled to the third electrode and that has a first end to which the first amplified signal is supplied and a second end from which the third amplified signal is output,
wherein the third electrode and the fourth electrode face each other, and
wherein a distance between the third electrode and the fourth electrode is not constant.

9. A power amplification device comprising:
a substrate;
a semiconductor chip mounted on the substrate and on which the power amplifier circuit according to claim 1 is formed; and
a matching circuit upstream or downstream of the power amplifier circuit.

10. A power amplification device comprising:
a first substrate comprising a first compound semiconductor and on which the power amplifier circuit according to claim 1 is formed; and
a second substrate comprising a single-element semiconductor or a second compound semiconductor and on which an amplifier is formed,
wherein the first compound semiconductor is different from the second compound semiconductor, and
wherein the amplifier is configured to amplify an input signal and to output the first signal.
